(19) United States
(12) Patent Application Publication
(10) Pub. No.: US 2021/0134695 A1
(43) Pub. Date: May 6, 2021

(54) INTERPOSER BOARD HAVING HEATING FUNCTION AND ELECTRONIC DEVICE USING THE SAME

(71) Applicant: ASTI GLOBAL INC., TAIWAN, Taichung City (TW)

(72) Inventors: CHIEN-SHOU LIAO, New Taipei City (TW); TE-FU CHANG, Taichung City (TW)

(21) Appl. No.: 16/903,491

(22) Filed: Jun. 17, 2020

(30) Foreign Application Priority Data
Nov. 6, 2019 (TW) 108140209

(51) Int. Cl. H01L 23/34; H01L 23/00; H05B 3/26

(52) U.S. Cl. CPC H01L 23/345; H01L 24/16; H01L 24/81; H01L 23/49827; H01L 2224/16227; H01L 2224/81007; H01L 2224/81238; H05B 3/26

(57) ABSTRACT

A non-conductive film having heating function and an electronic device using the same are provided. The electronic device includes a circuit substrate, an interposer board disposed on the circuit substrate, at least one electronic chip carried by the interposer board, a first non-conductive film disposed between the interposer board and the circuit substrate, and a second non-conductive film disposed between the at least one electronic chip and the interposer board, the at least one electronic chip being electrically connected to the circuit substrate through the interposer board. One of the first non-conductive film and the second non-conductive film is a type of non-conductive film having heating function, and the non-conductive film with heating function includes a non-conductive body and a plurality of micro heaters. The shape of the non-conductive body is changeable by heating, and the micro heaters are disposed on or in the non-conductive body.

### CROSS-REFERENCE TO RELATED PATENT APPLICATION

This application claims the benefit of priority to Taiwan Patent Application No. 108140209, filed on Nov. 6, 2019. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an interposer board and an electronic device, and more particularly to a non-conductive film having heating function and an electronic device using the same.

### BACKGROUND OF THE DISCLOSURE

Currently, an IC chip can be bonded on a PCB through a non-conductive film, but the conventional non-conductive film still has room for improvement.

### SUMMARY OF THE DISCLOSURE

In response to the above-referenced technical inadequacies, the present disclosure provides a non-conductive film having heating function and an electronic device using the same.

In one aspect, the present disclosure provides a non-conductive film having heating function, including a non-conductive body and a plurality of micro heaters. The shape of the non-conductive body is changeable by heating, and the micro heaters are disposed on or in the non-conductive body.

In another aspect, the present disclosure provides an electronic device including a circuit substrate, an interposer board disposed on the circuit substrate, at least one electronic chip carried by the interposer board, a first non-conductive film disposed between the interposer board and the circuit substrate, and a second non-conductive film disposed between the at least one electronic chip and the interposer board, and the at least one electronic chip being electrically connected to the circuit substrate through the interposer board. One of the first non-conductive film and the second non-conductive film is a non-conductive film having heating function, and the non-conductive film with heating function includes a non-conductive body and a plurality of micro heaters. The shape of the non-conductive body is changeable by heating, and the micro heaters are disposed on or in the non-conductive body.

In yet another aspect, the present disclosure provides an electronic device comprising a circuit substrate, at least one electronic chip carried by the circuit substrate, and a non-conductive film disposed between the at least one electronic chip and the circuit substrate. The non-conductive film includes a non-conductive body that is capable of changing shape thereof by heating, and a plurality of micro heaters disposed on or in the non-conductive body for heating the non-conductive body.

Therefore, by virtue of “the shape of the non-conductive body is changeable by heating” and “the micro heaters are disposed on or in the non-conductive body”, the micro heaters can be used to heat the non-conductive body. Furthermore, when an interposer board is disposed on a circuit substrate for carrying at least one electronic chip, a plurality of bottom conductive contacts of the interposer board are respectively electrically connected to a plurality of conductive substrate contacts of the circuit substrate respectively through a plurality of bottom solders, and the micro heaters are respectively adjacent to the bottom solders so as to respectively heat the bottom solders. Moreover, when the interposer board is disposed on the circuit substrate for carrying the at least one electronic chip, a plurality of top conductive contacts of the interposer board are respectively electrically connected to a plurality of conductive chip contacts of the at least one electronic chip respectively through a plurality of top solders, and the micro heaters are respectively adjacent to the top solders so as to respectively heat the top solders. In addition, when the at least one electronic chip is carried by the circuit substrate, the conductive chip contacts of the at least one electronic chip are respectively electrically connected to the conductive substrate contacts of the circuit substrate respectively through a plurality of solders, and the micro heaters are respectively adjacent to the solders so as to respectively heat the solders.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a schematic view of a non-conductive film having heating function according to a first embodiment of the present disclosure.

FIG. 2 is a function block of the relationship between a power input unit and a micro heater according to the first embodiment of the present disclosure.

FIG. 3 is a schematic view of a non-conductive film having heating function according to a second embodiment of the present disclosure.

FIG. 4 is an exploded schematic view of an electronic device according to a third embodiment of the present disclosure.

FIG. 5 is an assembled schematic view of the electronic device according to the third embodiment of the present disclosure.

FIG. 6 is an exploded schematic view of an electronic device according to a fourth embodiment of the present disclosure.

FIG. 7 is an assembled schematic view of the electronic device according to the fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

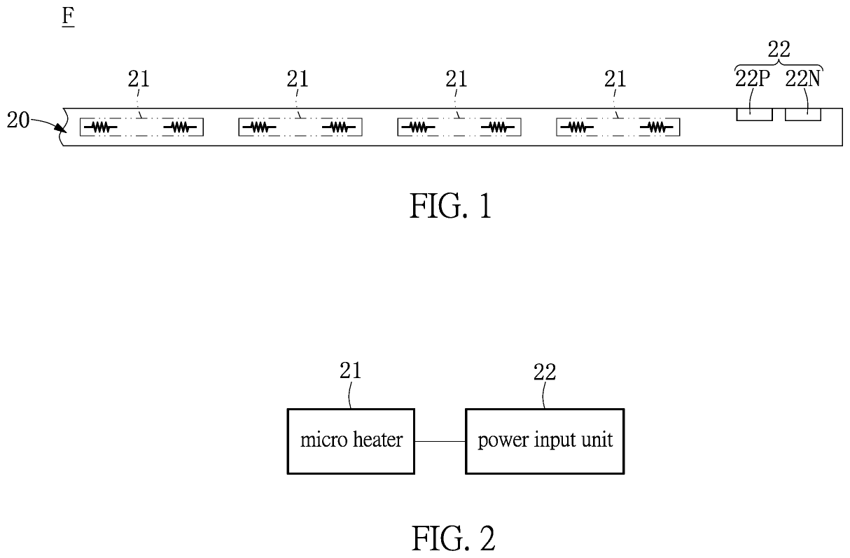

Referring to FIG. 1 and FIG. 2, a first embodiment of the present disclosure provides a non-conductive film F having heating function, including a non-conductive body 20 and a plurality of micro heaters 21. The shape of the non-conductive body 20 can be changeable by heating (or the non-conductive body 20 can be softened or partially melted), and the micro heaters 21 can be disposed on or in the non-conductive body 20.

For example, the non-conductive body 20 can be manufactured in advance, and then the micro heaters 21 are disposed on a top side or a bottom side of the prefabricated non-conductive body 20 (that is to say, the prefabricated micro heaters 21 can be disposed on the top side or the bottom side of the prefabricated non-conductive body 20). Or, the non-conductive body 20 and the micro heaters 21 can be concurrently manufactured, and the micro heaters 21 can be enclosed by the non-conductive body 20. However, the aforementioned description is merely an example and is not meant to limit the scope of the present disclosure.

For example, the micro heater 21 can be made as a conductive coil structure, and the micro heater 21 may be a surrounding micro heater, an L-shaped micro heater, a U-shaped micro heater, a single micro heater or a pair of micro heaters (as shown in FIG. 1). In addition, the micro heaters 21 can be in series connection with each other, in parallel connection with each other, or in series and parallel connection with each other. However, the aforementioned description for the micro heater 21 is merely an example and is not meant to limit the scope of the present disclosure.

More particularly, referring to FIG. 1 and FIG. 2, the non-conductive film F having heating function further includes a power input unit 22 disposed on a top side or a bottom side of the non-conductive body 20. For example, the power input unit 22 includes a positive contact 22P and a negative contact 22N that are disposed on the top side or the bottom side of the non-conductive body 20. As shown in FIG. 1, the positive contact 22P and the negative contact 22N are disposed on the top side of the non-conductive body 20, so that it is convenient for a user to input power into the positive contact 22P and the negative contact 22N from the top side of the non-conductive body 20 so as to turn on each micro heater 21 to heat the non-conductive body 20. However, the aforementioned description for the power input unit 22 is merely an example and is not meant to limit the scope of the present disclosure.

### Second Embodiment

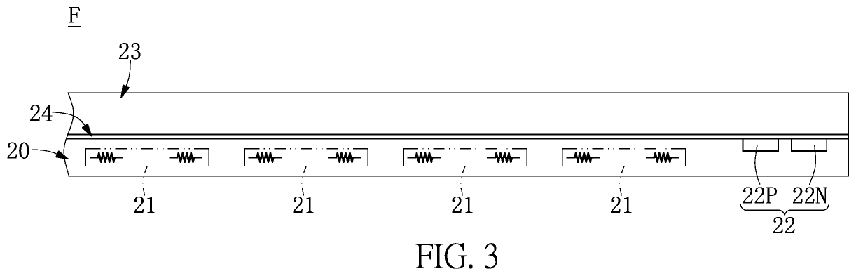

Referring to FIG. 3, a second embodiment of the present disclosure provides a non-conductive film F having heating function, including a non-conductive body 20 and a plurality of micro heaters 21, the shape of the non-conductive body 20 can be changeable by heating, and the micro heaters 21 can be disposed on or in the non-conductive body 20. Comparing FIG. 3 with FIG. 1, the difference between the second embodiment and the first embodiment is as follows: in the second embodiment, the non-conductive film F having heating function further includes a carrier substrate 23 and an adhesive layer 24 disposed on the carrier substrate 23, and the non-conductive body 20 is disposed on the adhesive layer 24 and carried by the carrier substrate 23. That is to say, the non-conductive film F having heating function can be temporarily disposed on the carrier substrate 23 through the adhesive layer 24. When the carrier substrate 23 with the adhesive layer 24 is separated from the non-conductive body 20, the non-conductive film F with the non-conductive body 20 and the micro heaters 21 can be adapted to any electronic device.

### Third Embodiment

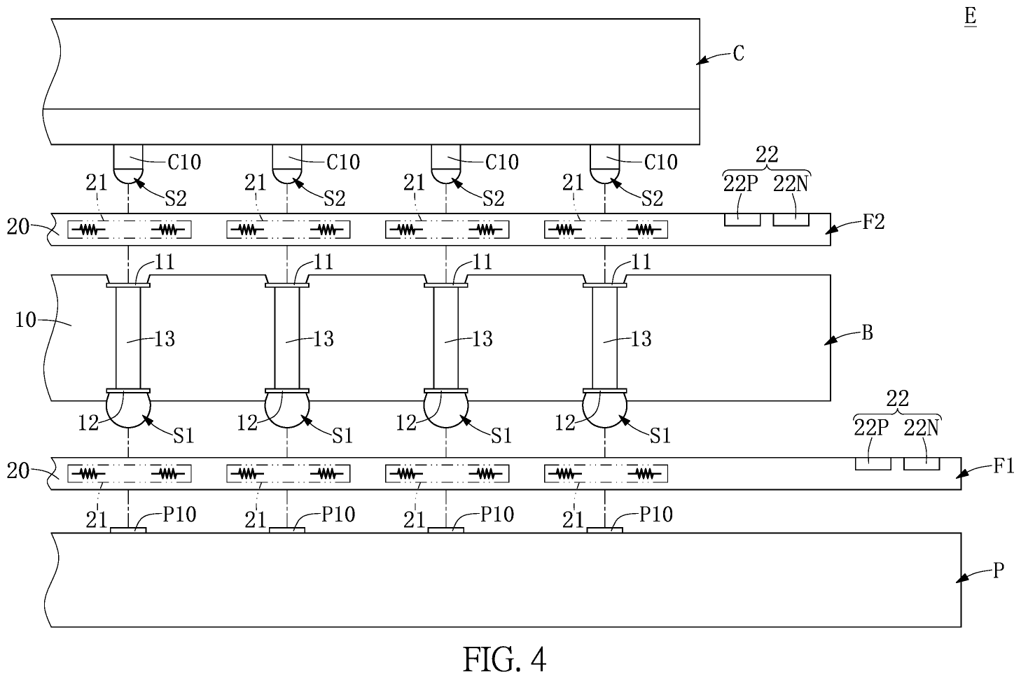

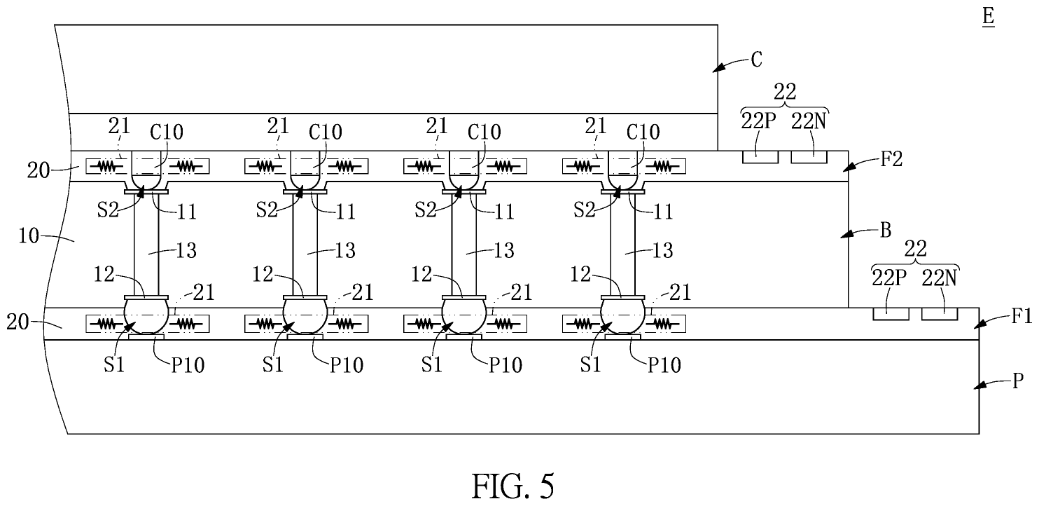

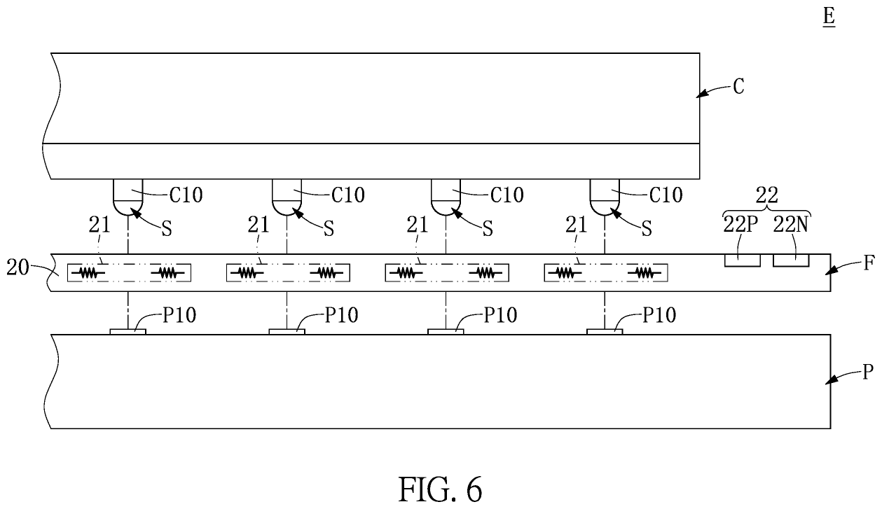

Referring to FIG. 4 and FIG. 5, a third embodiment of the present disclosure provides an electronic device E including a circuit substrate P, an interposer board B disposed on the circuit substrate P, at least one electronic chip C carried by the interposer board B, a first non-conductive film F1 disposed between the interposer board B and the circuit substrate P, and a second non-conductive film F2 disposed between the at least one electronic chip C and the interposer board B, and the at least one electronic chip C can be electrically connected to the circuit substrate P through the interposer board B. For example, one of the first non-conductive film F1 and the second non-conductive film F2 may be a non-conductive film F having heating function, and the non-conductive film F with heating function includes a non-conductive body 20 and a plurality of micro heaters 21. The shape of the non-conductive body 20 can be changeable by heating, and the micro heaters 21 can be disposed on or in the non-conductive body 20.

More particularly, referring to FIG. 4 and FIG. 5, the interposer board B includes an insulating body 10, a plurality of top conductive contacts 11 disposed on a top side of the insulating body 10, a plurality of bottom conductive contacts 12 disposed on a bottom side of the insulating body 10, and a plurality of conductive connection structures 13 disposed inside the insulating body 10, and the conductive connection structures 13 are respectively electrically connected to the top conductive contacts 11 and respectively electrically connected to the bottom conductive contacts 12 so as to electrically connect each of the conductive connection structures 13 between the corresponding top conductive contact 11 and the corresponding bottom conductive contact 12.

More particularly, as shown in FIG. 5, when the non-conductive film F used as the first non-conductive film F1 is disposed between the interposer board B and the circuit substrate P, the micro heaters 21 are respectively adjacent to the bottom conductive contacts 12, so that the non-conductive film F used as the first non-conductive film F1 can be heated by the micro heaters 21. In addition, the bottom conductive contacts 12 are respectively electrically connected to a plurality of conductive substrate contacts P10 of the circuit substrate P respectively through a plurality of bottom solders S1, and the micro heaters 21 are respectively adjacent to the bottom solders S1 so as to respectively heat the bottom solders S1.

More particularly, as shown in FIG. 5, when the non-conductive film F used as the second non-conductive film F2 is disposed between the at least one electronic chip C and the interposer board B, the micro heaters 21 are respectively adjacent to the top conductive contacts 11, so that the non-conductive film F used as the second non-conductive film F2 can be heated by the micro heaters 21. In addition, the top conductive contacts 11 are respectively electrically connected to a plurality of conductive chip contacts C10 of the at least one electronic chip C respectively through a plurality of top solders S2, and the micro heaters 21 are respectively adjacent to the top solders S2 so as to respectively heat the top solders S2.

For example, the micro heater 21 may be a surrounding micro heater that surrounds the bottom solders S1 or the top solders S2; or the micro heater 21 can also be arranged on any three sides beside the bottom solders S1 or any three sides the top solders S2; or the micro heater 21 can also be arranged at any two sides of the bottom solders S1 or at any two sides of the top solders S2 (as shown in FIG. 5); or the micro heater 21 can also be arranged at any one side of the bottom solders S1 or at any one side the top solders S2. In addition, the micro heaters 21 are in series connection with each other, in parallel connection with each other, or in series and parallel connection with each other. However, the aforementioned description is merely an example and is not meant to limit the scope of the present disclosure.

Therefore, referring to FIG. 4 and FIG. 5, when the top solders S2 are disposed between the top conductive contacts 11 and the conductive chip contacts C10, and the bottom solders S1 are disposed between the bottom conductive contacts 12 and the conductive substrate contacts P10, the top solders S2 and the bottom solders S1 can be heated by the micro heaters 21, so that the at least one electronic chip C can be positioned on the interposer board B by heating the top solders S2, and the interposer board B can be positioned on the circuit substrate P by heating the bottom solders S1. For example, the top solders S2 and the bottom solders S1 may be solder balls, solder pastes or any conductive materials for bonding the at least one electronic chip C. However, the aforementioned description for the top solders S2 and the bottom solders S1 is merely an example and is not meant to limit the scope of the present disclosure.

More particularly, referring to FIG. 4 and FIG. 5, when the first non-conductive film F1 and the second non-conductive film F2 are heated by driving the micro heaters 21, the first non-conductive film F 1 can be firmly positioned between the insulating body 10 and the circuit substrate P by heating so as to fill gaps between the insulating body 10 and the circuit substrate P with the first non-conductive film F1, and the second non-conductive film F2 can be firmly positioned between the at least one electronic chip C and the insulating body 10 by heating so as to fill gaps between the at least one electronic chip C and the insulating body 10 with the second non-conductive film F2. For example, when the first non-conductive film F1 and the second non-conductive film F2 are heated by the micro heaters 21, the first non-conductive film F1 and the second non-conductive film F2 are deformed due to heating, so that the gaps formed between the insulating body 10 and the circuit substrate P can be fully filled with the first non-conductive film F1, and the gaps formed between the at least one electronic chip C and the insulating body 10 can be fully filled with the second non-conductive film F2.

### Fourth Embodiment

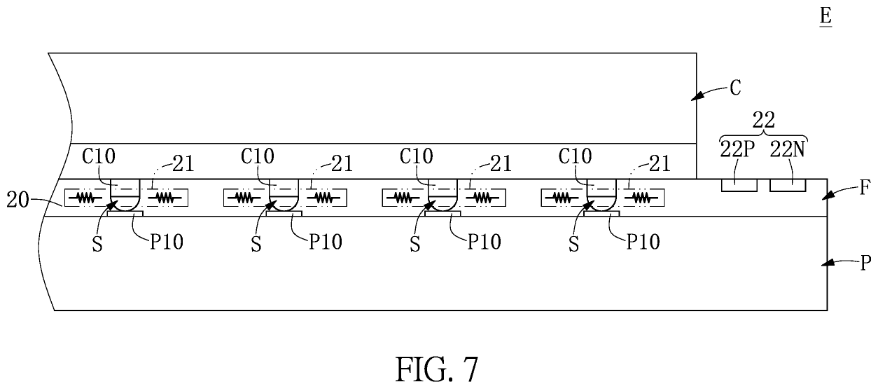

Referring to FIG. 4 and FIG. 5, a fourth embodiment of the present disclosure provides an electronic device E including a circuit substrate P, at least one electronic chip C carried by the circuit substrate P, and a non-conductive film F disposed between the at least one electronic chip C and the circuit substrate P. The non-conductive film F includes a non-conductive body 20 and a plurality of micro heaters 21. The non-conductive body 20 is capable of changing shape thereof by heating, and the micro heaters 21 are disposed on or in the non-conductive body 20 for heating the non-conductive body 20. Comparing FIG. 6 with FIG. 4, and FIG. 7 with FIG. 5, the difference between the fourth embodiment and the third embodiment is as follows: the electronic device E of the fourth embodiment can omit the interposer board B as shown in the third embodiment.

More particularly, referring to FIG. 6 and FIG. 7, when at least one electronic chip C is carried by a circuit substrate P, the non-conductive film F can be disposed between the at least one electronic chip C and the circuit substrate P. In addition, the at least one electronic chip C includes a plurality of conductive chip contacts C10, the circuit substrate P includes a plurality of conductive substrate contacts P10, and the conductive chip contacts C10 are respectively electrically connected to the conductive substrate contacts P10 respectively through a plurality of solders S, and the micro heaters 21 are respectively adjacent to the solders S so as to respectively heat the solders S.

Therefore, referring to FIG. 6 and FIG. 7, when the solders S are disposed between the conductive chip contacts C10 and the conductive substrate contacts P10, the solders S can be heated by the micro heaters 21, so that the at least one electronic chip C can be positioned on the circuit substrate P by heating the solders S1. For example, the solders S may be solder balls, solder pastes or any conductive materials for bonding the at least one electronic chip C. However, the aforementioned description for the solders S is merely an example and is not meant to limit the scope of the present disclosure.

More particularly, referring to FIG. 6 and FIG. 7, when the non-conductive film F is heated by driving the micro heaters 21, the non-conductive film F can be firmly positioned between the at least one electronic chip C and the circuit substrate P by heating so as to fill gaps between the at least one electronic chip C and the circuit substrate P with the non-conductive film F. For example, when the non-conductive film F is heated by the micro heaters 21, the non-conductive film F is deformed due to heating, so that the gaps formed between the at least one electronic chip C and the circuit substrate P can be fully filled with the non-conductive film

In conclusion, by virtue of “the shape of the non-conductive body 20 is changeable by heating” and “the micro heaters 21 are disposed on or in the non-conductive body 20”, the micro heaters 21 can be used to heat the non-conductive body 20. Furthermore, when an interposer board B is disposed on a circuit substrate P for carrying at least one electronic chip C, a plurality of bottom conductive contacts 12 of the interposer board B are respectively electrically connected to a plurality of conductive substrate contacts P10 of the circuit substrate P respectively through a plurality of bottom solders S1, and the micro heaters 21 are respectively adjacent to the bottom solders S1 so as to respectively heat the bottom solders S1. Moreover, when the interposer board B is disposed on the circuit substrate P for carrying the at least one electronic chip C, a plurality of top conductive contacts 11 of the interposer board B are respectively electrically connected to a plurality of conductive chip contacts C10 of the at least one electronic chip C respectively through a plurality of top solders S2, and the micro heaters 21 are respectively adjacent to the top solders S2 so as to respectively heat the top solders S2. In addition, when the at least one electronic chip C is carried by the circuit substrate P, the conductive chip contacts C10 of the at least one electronic chip C are respectively electrically connected to the conductive substrate contacts P10 of the circuit substrate P respectively through a plurality of solders S, and the micro heaters 21 are respectively adjacent to the solders S so as to respectively heat the solders S.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A non-conductive film having heating function, comprising:
a non-conductive body, wherein a shape of the non-conductive body is changeable by heating; and
a plurality of micro heaters disposed on or in the non-conductive body.

2. The non-conductive film according to claim 1, further comprising: a carrier substrate and an adhesive layer disposed on the carrier substrate, the non-conductive body being disposed on the adhesive layer and carried by the carrier substrate.

3. The non-conductive film according to claim 1, further comprising: a power input unit disposed on a top side or a bottom side of the non-conductive body.

4. The non-conductive film according to claim 1, wherein when an interposer board is disposed on a circuit substrate for carrying at least one electronic chip, the non-conductive film is used as a first non-conductive film and is disposed between the interposer board and the circuit substrate, and the at least one electronic chip is electrically connected to the circuit substrate through the interposer board; wherein the interposer board includes an insulating body, a plurality of top conductive contacts disposed on a top side of the insulating body, a plurality of bottom conductive contacts disposed on a bottom side of the insulating body, and a plurality of conductive connection structures disposed inside the insulating body, and the conductive connection structures are respectively electrically connected to the top conductive contacts and respectively electrically connected to the bottom conductive contacts so as to electrically connect each of the conductive connection structures between the corresponding top conductive contact and the corresponding bottom conductive contact; wherein the micro heaters are respectively adjacent to the bottom conductive contacts, and the non-conductive film used as the first non-conductive film are heated by the micro heaters; wherein the bottom conductive contacts are respectively electrically connected to a plurality of conductive substrate contacts of the circuit substrate respectively through a plurality of bottom solders, and the micro heaters are respectively adjacent to the bottom solders so as to respectively heat the bottom solders.

5. The non-conductive film according to claim 1, wherein when an interposer board is disposed on a circuit substrate for carrying at least one electronic chip, the non-conductive film is used as a second non-conductive film and is disposed between the at least one electronic chip and the interposer board, and the at least one electronic chip is electrically connected to the circuit substrate through the interposer board; wherein the interposer board includes an insulating body, a plurality of top conductive contacts disposed on a top side of the insulating body, a plurality of bottom conductive contacts disposed on a bottom side of the insulating body, and a plurality of conductive connection structures disposed inside the insulating body, and the conductive connection structures are respectively electrically connected to the top conductive contacts and respectively electrically connected to the bottom conductive contacts so as to electrically connect each of the conductive connection structures between the corresponding top conductive contact and the corresponding bottom conductive contact; wherein the micro heaters are respectively adjacent to the top conductive contacts, and the non-conductive film used as the second non-conductive film are heated by the micro heaters; wherein the top conductive contacts are respectively electrically connected to a plurality of conductive chip contacts of the at least one electronic chip respectively through a plurality of top solders, and the micro heaters are respectively adjacent to the top solders so as to respectively heat the top solders.

6. The non-conductive film according to claim 1, wherein when at least one electronic chip is carried by a circuit substrate, the non-conductive film is disposed between the at least one electronic chip and the circuit substrate; wherein the at least one electronic chip includes a plurality of conductive chip contacts, the circuit substrate includes a plurality of conductive substrate contacts, and the conductive chip contacts are respectively electrically connected to the conductive substrate contacts respectively through a plurality of solders; wherein the micro heaters are respectively adjacent to the solders so as to respectively heat the solders.

7. An electronic device comprising a circuit substrate, an interposer board disposed on the circuit substrate, at least one electronic chip carried by the interposer board, a first non-conductive film disposed between the interposer board and the circuit substrate, and a second non-conductive film disposed between the at least one electronic chip and the interposer board, the at least one electronic chip being electrically connected to the circuit substrate through the interposer board, wherein one of the first non-conductive film and the second non-conductive film is a non-conductive film having heating function, and the non-conductive film with heating function comprises:
a non-conductive body, wherein a shape of the non-conductive body is changeable by heating; and
a plurality of micro heaters disposed on or in the non-conductive body.

8. The electronic device according to claim 7, wherein the interposer board includes an insulating body, a plurality of top conductive contacts disposed on a top side of the insulating body, a plurality of bottom conductive contacts disposed on a bottom side of the insulating body, and a plurality of conductive connection structures disposed inside the insulating body, and the conductive connection structures are respectively electrically connected to the top conductive contacts and respectively electrically connected to the bottom conductive contacts so as to electrically connect each of the conductive connection structures between the corresponding top conductive contact and the corresponding bottom conductive contact; wherein when the non-conductive film used as the first non-conductive film is disposed between the interposer board and the circuit substrate, the micro heaters are respectively adjacent to the bottom conductive contacts, and the non-conductive film used as the first non-conductive film are heated by the micro heaters; wherein the bottom conductive contacts are respectively electrically connected to a plurality of conductive substrate contacts of the circuit substrate respectively through a plurality of bottom solders, and the micro heaters are respectively adjacent to the bottom solders so as to respectively heat the bottom solders.

9. The electronic device according to claim 7, wherein the interposer board includes an insulating body, a plurality of top conductive contacts disposed on a top side of the insulating body, a plurality of bottom conductive contacts disposed on a bottom side of the insulating body, and a plurality of conductive connection structures disposed inside the insulating body, and the conductive connection structures are respectively electrically connected to the top conductive contacts and respectively electrically connected to the bottom conductive contacts so as to electrically connect each of the conductive connection structures between the corresponding top conductive contact and the corresponding bottom conductive contact; wherein when the non-conductive film used as the second non-conductive film is disposed between the at least one electronic chip and the interposer board, the micro heaters are respectively adjacent to the top conductive contacts, and the non-conductive film used as the second non-conductive film are heated by the micro heaters; wherein the top conductive contacts are respectively electrically connected to a plurality of conductive chip contacts of the at least one electronic chip respectively through a plurality of top solders, and the micro heaters are respectively adjacent to the top solders so as to respectively heat the top solders.

10. An electronic device comprising a circuit substrate, at least one electronic chip carried by the circuit substrate, and a non-conductive film disposed between the at least one electronic chip and the circuit substrate, wherein the non-conductive film comprises:
a non-conductive body being capable of changing shape thereof by heating; and
a plurality of micro heaters disposed on or in the non-conductive body for heating the non-conductive body.
